(19) United States
(12) Patent Application Publication
(10) Pub. No.: US 2014/0105594 A1
(43) Pub. Date: Apr. 17, 2014

(54) DETECTING DEVICE AND DETECTING METHOD

(71) Applicant: AVERMEDIA TECHNOLOGIES, INC., New Taipei City (TW)

(72) Inventors: Chien-Ming YEH, NEW TAIPEI CITY (TW); Yu-Hsiang CHEN, NEW TAIPEI CITY (TW); Neng-Chia LEE, TAIPEI HSIEN (TW)

(73) Assignee: AVERMEDIA TECHNOLOGIES, INC., NEW TAIPEI CITY (TW)

(21) Appl. No.: 13/652,465

(22) Filed: Oct. 15, 2012

(51) Int. Cl. G01R 31/00; H04B 10/08

(52) U.S. Cl. 398/17; 324/750.01; 398/38

(57) ABSTRACT

A detection device is electrically connected to a controlled device through a power line and configured for detecting a power condition of the controlled device. The detection device at least includes a power detection module, a processing unit, and an infrared transmitter. The power detection module is configured for detecting an input current transmitted through the power line from the controlled device and converting the input current to an output voltage signal. The processing unit is configured for receiving the output voltage signal and determining the power condition of the controlled device based on a voltage level of the output voltage signal. The infrared transmitter is configured for transmitting an infrared signal based on the determined result of the processing unit to switch the controlled device such that the controlled device performs a corresponding operation. Further, a detecting method is also disclosed.

### BACKGROUND

1. Field of Invention

The present invention relates to a detection device and a detecting method. More particularly, the present invention relates to a power detection device and a power detecting method.

2. Description of Related Art

With rapid development of technology, electronic devices, hereinafter referred to as controlled devices, for people are capable of being distantly operated by remote controls. For example, the remote control can turn on/off a power source of a recorder, adjust the recorder's volume and frame quality, switch to different working modes of the recorder, and so forth.

FIG. 1 illustrates a circuit diagram of a remote control operates a controlled device. As shown in FIG. 1, instead of touching controlled device 140, remote control 120 can operate controlled device 140 distantly. By using infrared transmitter 160 in remote control 120, remote control 120 can transmit an infrared signal to a receiver of controlled device 140 to operate controlled device 140 from far away. The infrared signal has specific control codes to make remote control 120 correspondingly perform a corresponding operation to controlled device 140 under different infrared signals.

However, in using the remote controls to operate the controlled devices, people are normally unaware of the power condition of the controlled devices. When the controlled devices malfunction, they cannot determine the malfunction results from that the controlled devices are crashed, external power sources are damaged, or other problems.

Therefore, it is necessary to make users of the controlled devices to clearly understand the controlled devices are in which power condition, and to make the controlled devices correctly operate after detection.

### SUMMARY

An aspect of the invention is to provide a detection device. The detection device can detect a power condition of a controlled device to make a user clearly understand the power condition of the controlled device and to avoid the user operate the controlled device incorrectly.

Another aspect of the invention is to provide a detecting method. The detecting method can detect and determine a power condition of a controlled device and make the controlled device to be operated correctly.

In one embodiment of the present invention, a detection device which is electrically connected to a controlled device through a power line configured for detecting a power condition of the controlled device. The detection device at least includes a power detection module, a processing unit, and an infrared transmitter. The power detection module is configured for detecting an input current transmitted through the power line from the controlled device and converting the input current to an output voltage signal; the processing unit is electrically connected to the power detection module, and configured for receiving the output voltage signal and determining the power condition of the controlled device based on a voltage level of the output voltage signal; the infrared transmitter is electrically connected to the processing unit, and configured for transmitting an infrared signal based on a determined result of the processing unit to switch the controlled device such that the controlled device performs a corresponding operation.

In another embodiment of the present invention, a detecting method is configured for detecting a controlled device. The detecting method includes the flowing steps: an input current is detected which is transmitted from the controlled device through a power line by a power detection module under different power conditions of the controlled device; information corresponding to the input current is recorded; and the power condition of the controlled device is determined in accordance with the information corresponding to the input current.

A user can correctly operate the controlled device with a clear understanding of the power condition of the controlled device according to the invention.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 illustrates a circuit diagram of a remote control operating a controlled device.

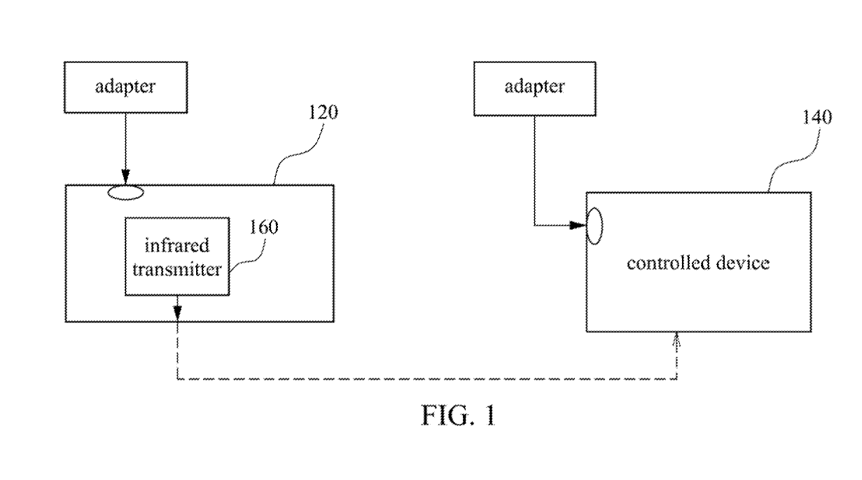

FIG. 2 illustrates a circuit diagram of a detection device according to an embodiment of the invention.

FIG. 3 illustrates a circuit diagram of a power detection module according to an embodiment of the invention.

FIG. 4 illustrates the relationship between a certain current/voltage range and a power condition of a controlled device according to an embodiment of the invention.

FIG. 5 illustrates a circuit diagram of a detection device according to another embodiment of the invention.

FIG. 6 illustrates a circuit diagram of a detection device according to still another embodiment of the invention.

FIG. 7 illustrates a flowchart of a detecting method according to an embodiment of the invention.

FIG. 8 illustrates a flowchart of a detecting method according to another embodiment of the invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The present invention will now be described more fully hereinafter with reference to the accompanying drawings, in which exemplary embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

As used herein, “around”, “about” or “approximately” shall generally mean within 20 percent, preferably within 10 percent, and more preferably within 5 percent of a given value or range. Numerical quantities given herein are approximate; meaning that the term “around”, “about” or “approximately” can be inferred if not expressly stated.

In the following description and claims, the terms “coupled” and “connected,” along with their derivatives, may be used. In particular embodiments, “connected” and “coupled” may be used to indicate that two or more elements are in direct physical or electrical contact with each other, or may also mean that two or more elements may be in indirect contact with each other. “Coupled” and “connected” may still be used to indicate that two or more elements cooperate or interact with each other.

The following embodiments of the invention disclose a detection device which can detect a power condition of a controlled device, for example, a recorder, to make a user correctly operate the controlled device with a clear understanding of the power condition of the controlled device.

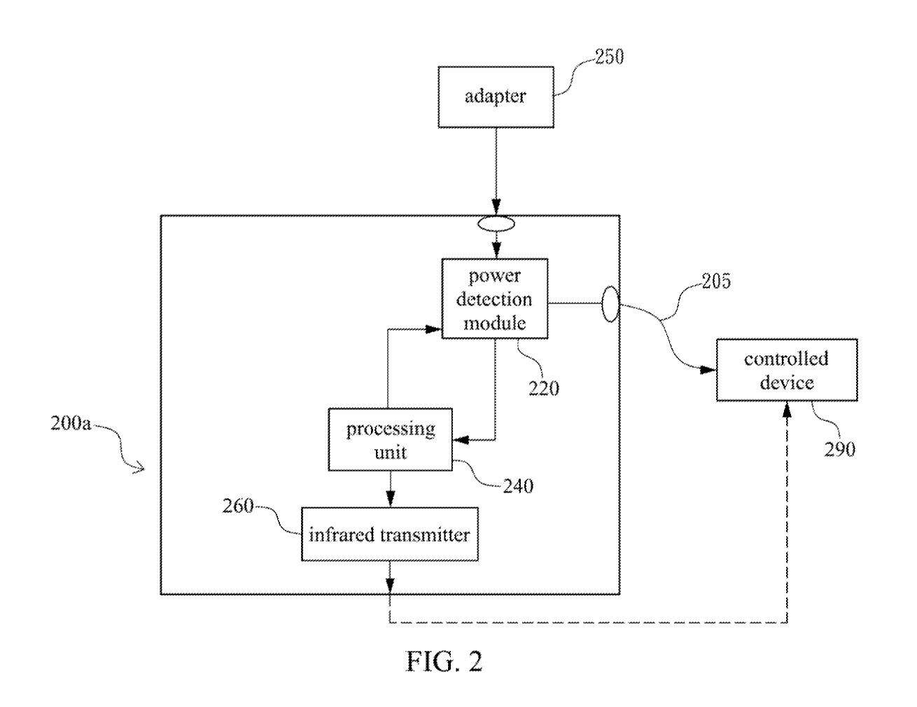

FIG. 2 illustrates a circuit diagram of a detection device according to an embodiment of the invention. Detection device 200a is electrically connected to controlled device 290 through a power line 205 and configured for detecting a power condition of controlled device 290. Detection device 200a at least includes power detection module 220 and processing unit 240. Power detection module 220 is configured for detecting an input current transmitted through power line 205 from controlled device 290 and converting the input current to an output voltage signal. Processing unit 240 is electrically connected to power detection module 220 and configured for receiving the output voltage signal and determining the power condition of controlled device 290 based on a voltage level of the output voltage signal.

Power detection module 220 converts the input current detected from controlled device 290 to the output voltage signal, and transmits the output voltage signal to processing unit 240. Processing unit 240 records the voltage level of the output voltage signal and determines the power condition of controlled device 290 according to a recording result. Then, detection device 200a operates controlled device 290 corresponding to the determined different power conditions.

Specifically, detection device 200a can further include infrared transmitter 260, wherein infrared transmitter 260 is electrically connected to processing unit 240 and transmits an infrared signal to controlled device 290, for example, a receiver of controlled device 290, based on a determined result of processing unit 240 to switch controlled device 290 such that controlled device 290 performs a corresponding operation.

Furthermore, adapter 250 in FIG. 2 is electrically connected to power detection module 220 and converts an alternating current (AC) power source to a direct current (DC) power source for power detection module 220.

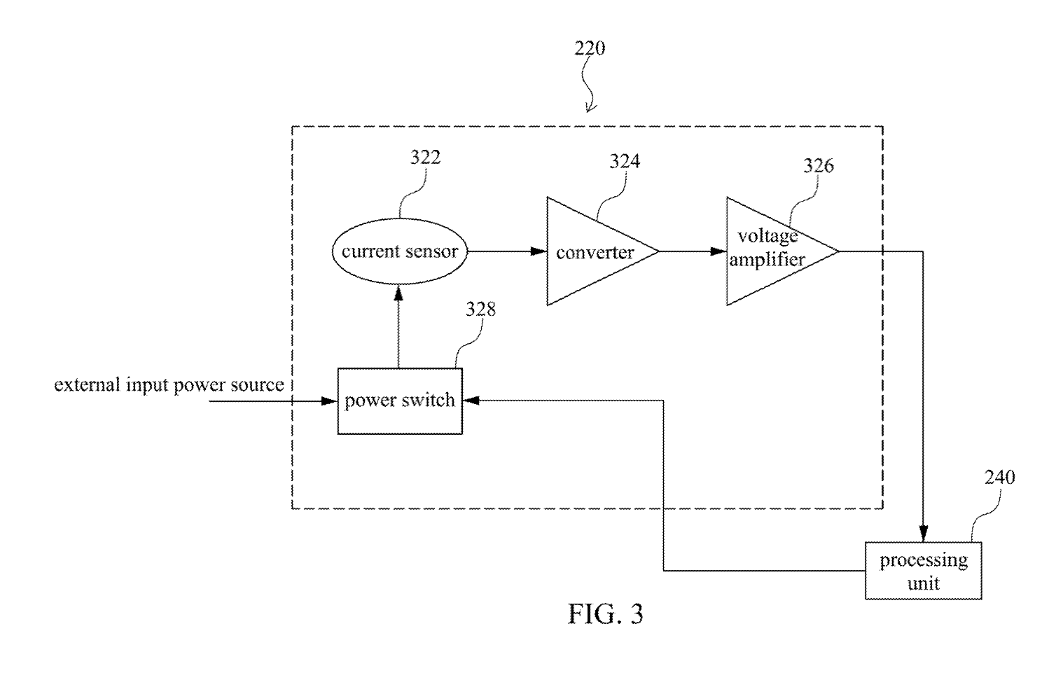

FIG. 3 illustrates a circuit diagram of a power detection module according to an embodiment of the invention. Power detection module 220 shown in FIG. 3 can be applied into detection device 200a shown in FIG. 2 but is not limited to this. As shown in FIG. 3, power detection module 220 includes current sensor 322, converter 324, voltage amplifier 326, and power switch 328. Current sensor 322 is configured for sensing the input current detected from controlled device 290 (see FIG. 2) and outputting a current signal corresponding to the input signal; converter 324 is electrically connected to current sensor 322 and configured for converting the current signal outputted from current sensor 322 to an internal voltage signal; voltage amplifier 326 is electrically connected to converter 324 and configured for amplifying the internal voltage signal to generate the output voltage signal outputted from power detection module 220; and power switch 328 is electrically connected to processing unit 240 in FIG. 2 and current sensor 322. Power switch 328 is controlled by processing unit 240 to conduct or block the input current flowing to current sensor 322.

Please refer to FIG. 2 and FIG. 3, in operation, power detection module 220 detects the input current transmitted through power line 205 from controlled device 290, and converts the input current to the internal voltage signal with converter 324, and then amplifies the internal voltage signal with voltage amplifier 326 to generate the output voltage signal. Processing unit 240 records the voltage level of the output voltage signal and determines the power condition of controlled device 290 according to the voltage level of the output voltage signal.

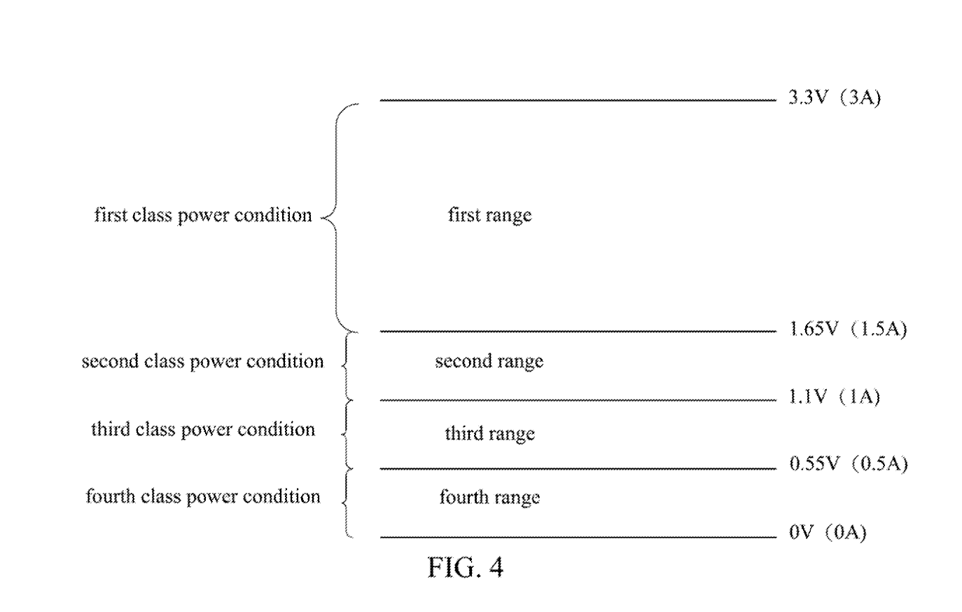

FIG. 4 illustrates the relationship between a certain current/voltage range and a power condition of a controlled device according to an embodiment of the invention. As shown in FIG. 4, any controlled device can be detected of its current or corresponding voltage by detection device 200a and determined of its power condition afterwards.

Approximately, the controlled device has four classes of power conditions which are a first class, second class, third class, and fourth class power condition, respectively. The power conditions are separately corresponded to different current/voltage ranges which are a first, second, third, and fourth range. Specifically, the first range corresponds to the first class power condition (e.g. a normal power condition); the second range corresponds to the second class power condition (e.g., a fault power condition); the third range corresponds to the third class power condition (e.g., a standby or a sleeping power condition); and the fourth range corresponds to the fourth class power condition (e.g., a power off condition).

When a value of the input current or the output voltage signal of controlled device 290 described above is in a certain range, processing unit 240 in FIG. 2 determines the power condition of controlled device 290. An example will be presented as follows. It is noted that the current/voltage determining standard in FIG. 4 is only one embodiment in the invention, and it does not indicate all the conditions of different controlled devices. Various determining standards can be set for various controlled devices.

As shown in FIG. 4, for example, when a value of an operational voltage of a controlled device is in the range of 1.65V to 3.3V (a value of an operational current is in the range of 1.5 A to 3 A), the operational voltage/current is in the first range, and processing unit 240 in FIG. 2 determines that the controlled device described above is operating in the first class power condition (i.e. the normal power condition); when the value of the operational voltage of the controlled device is in the range of 1.1V to 1.65V (the value of the operational current is in the range of 1 A to 1.5 A), the operational voltage/current is in the second range, and processing unit 240 determines that the controlled device described above is in the second class power condition (i.e. the fault power condition); when the value of the operational voltage of the controlled device is in the range of 0.55V to 1.1V (the value of the operational current is in the range of 0.5 A to 1 A), the operational voltage/current is in the third range, and processing unit 240 determines that the controlled device described above is in the third class power condition (i.e. the standby or the sleeping power condition); when the value of the operational voltage of the controlled device is in the range of 0V to 0.55V (the value of the operational current is in the range of 0 A to 0.5 A), the operational voltage/current is in the fourth range, and processing unit 240 determines that the controlled device described above is in the fourth class power condition (i.e. the power off condition).

Please refer to FIG. 2 and FIG. 4 at the same time, it should be noted that after processing unit 240 determines the power condition of controlled device 290, detection device 200a operates controlled device 290 correspondingly. In one embodiment, when processing unit 240 determines that controlled device 290 is in the normal power condition, the standby power condition, or the sleeping power condition, processing unit 240 controls infrared transmitter 260 to switch controlled device 290. When processing unit 240 determines that controlled device 290 is in the fault power condition, processing unit 240 resets controlled device 290 to return to the normal power condition. Controlled device 290 then can be switched by infrared transmitter 260.

For example, if controlled device 290 is a recorder with a scheduled recording function, and a user leaves after setting the scheduled recording function, processing unit 240 can instruct detection device 200a to operate the recorder after determining the power condition of the recorder when the recorder suddenly stop recording. For example, if processing unit 240 determines that controlled device 290 is in the fault power condition, processing unit 240 in detection device 200a resets controlled device 290 automatically. The user needs not to operate the recorder manually but the recorder can still keep recording with the absence of the user.

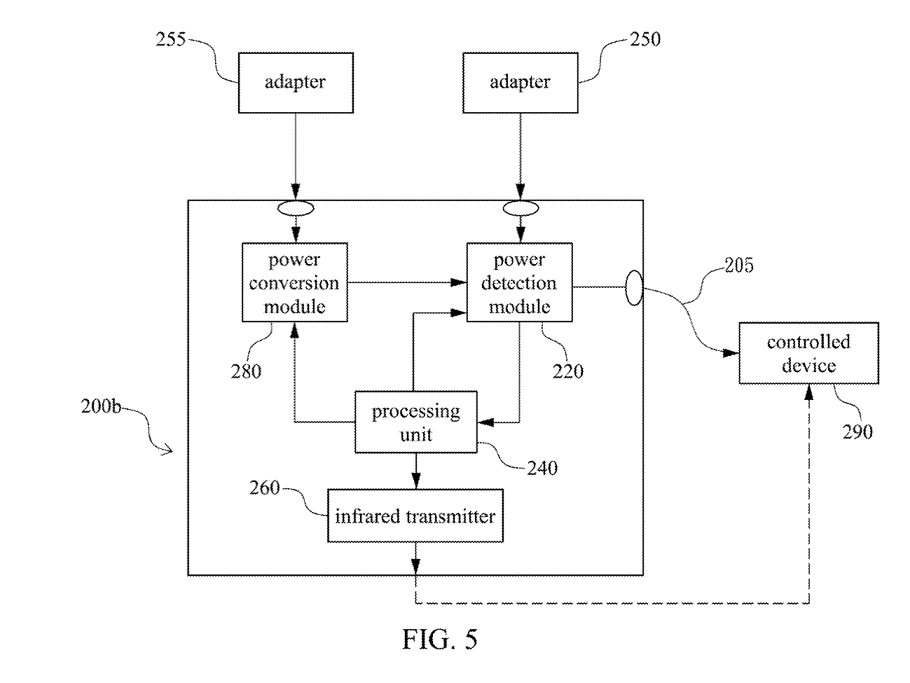

FIG. 5 illustrates a circuit diagram of a detection device according to another embodiment of the invention. Detection device 200b and detection device 200a include some similar or identical elements, but detection device 200b further includes power conversion module 280.

Power conversion module 280 is electrically connected to processing unit 240 and power detection module 220 and controlled by processing unit 240 in FIG. 5. When the AC power source from adapter 250 cannot supply the electricity, power conversion module 280 is configured for converting the external input power source to the operational power source for power detection module 220. In one embodiment, the external input power source is converted from the original AC power source to a DC power source through adapter 255. Power conversion module 280 then can be a DC voltage conversion module to convert the voltage corresponding to the DC power source to the voltage corresponding to the operational power source such that power detection module 220 can operate.

Furthermore, when processing unit 240 determines that controlled device 290 is in the power off state, processing unit 240 can wake up or start controlled device 290 (e.g., send a control signal to wake up or start controlled device 290 by infrared transmitter 260). If controlled device 290 cannot be woken up or started (the reason might be the damage or breakdown of the components or circuits which provide the power to controlled device 290), power conversion module 280 can convert the external input power source received from adapter 255 to the operational power source, and transmit the operational power source for controlled device 290 through power detection module 220 to put controlled device 290 back to the normal power condition. Controlled device 290 then can be switched by infrared transmitter 260 and continuously operate normally.

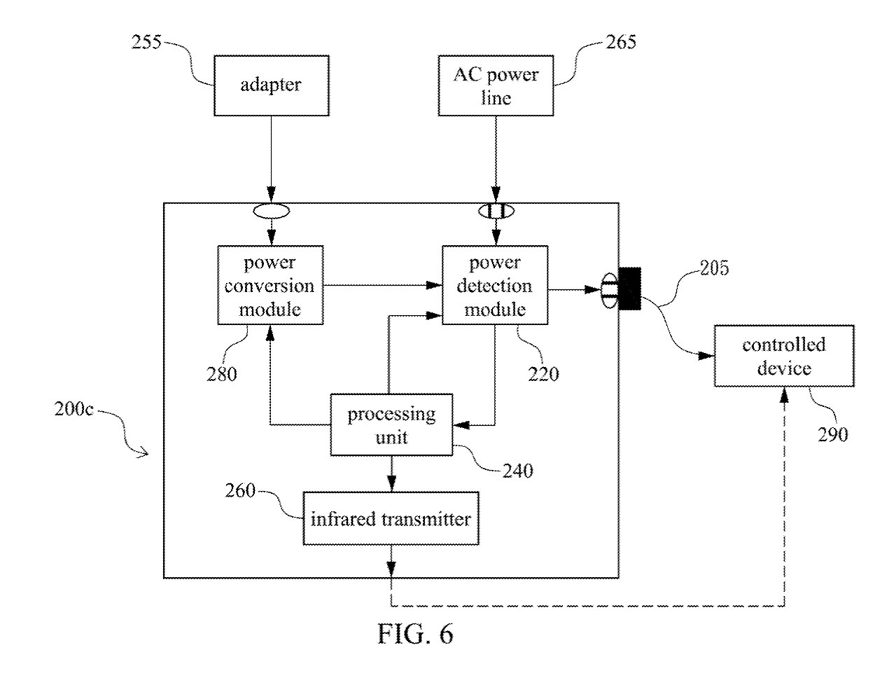

FIG. 6 illustrates a circuit diagram of a detection device according to another embodiment of the invention. The elements and their functions in detection device 200c correspond to those in detection device 200b so as not to be mentioned herein. It is noted that adapter 255 can be replaced by AC power line 265 comparing with the embodiment in FIG. 5 (i.e., power detection module 220 can use both DC power source and AC power source as the operational power sources).

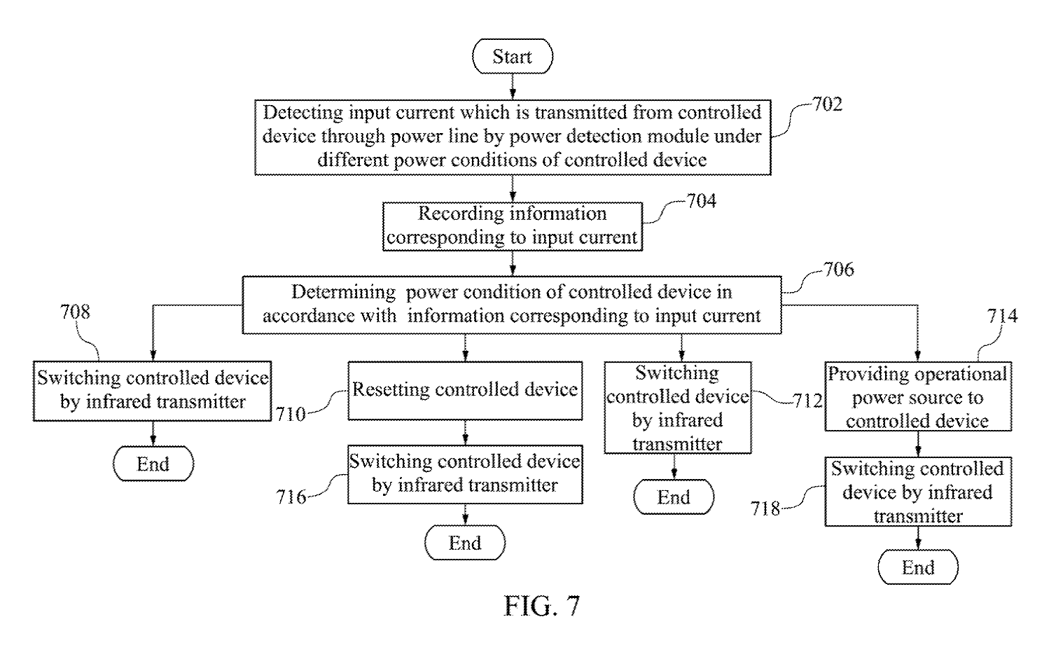

FIG. 7 illustrates a flowchart of a detecting method according to an embodiment of the invention. For the purpose of a clear and convenient illustration, please refer to FIG. 2 and FIG. 7 at the same time to understand the following embodiment. Before processing the detecting method, the user can switch controlled device 290 into various power conditions to record the current and voltage ranges of controlled device 290 by processing unit 240 of detection device 200a. The record becomes a standard for process nit 240 to determine the power condition of controlled device 290.

The detecting method in the embodiment includes the following steps. At first, an input current which is transmitted from controlled device 290 is detected through power line 205 by power detection module 220 under different power conditions of controlled device 290 (step 702), and information corresponding to the input current is recorded (step 704), then the power condition of controlled device 290 is determined in accordance with the information corresponding to the input current (step 706).

In other embodiments, step 702 and 704 of the detecting method can further include converting the input current to an output voltage signal, and step 706 can further include determining the power condition of controlled device 290 according to a voltage level of the output voltage signal.

In one embodiment, please refer to FIG. 4 and FIG. 7 at the same time, the step that the power condition of controlled device 290 is determined (step 706) further includes: controlled device 290 is determined operating in a first class power condition (i.e., a normal power condition) when the input current is in a first range of FIG. 4; controlled device 290 is determined operating in a second class power condition (i.e., a fault power condition) when the input current is in a second range; controlled device 290 is determined operating in a third class power condition (i.e., a standby or a sleeping power condition) when the input current is in a third range; controlled device 290 is determined operating in a fourth class power condition (i.e., a power off condition) when the input current is in a fourth range.

When controlled device 290 is determined operating in the first class power condition (i.e., the normal power condition), enter step 708, controlled device 290 is switched by infrared transmitter 260 shown in FIG. 2; when controlled device 290 is determined operating in the second class power condition (i.e., the fault power condition), enter step 710 controlled device 290 is reset, and then enter step 716, controlled device 290 is switched by infrared transmitter 260.

When controlled device 290 is determined operating in the third class power condition (i.e., the standby or the sleeping power condition), enter step 712, controlled device 290 is switched by infrared transmitter 260 which is the same as step 708; when controlled device 290 is determined operating in the fourth class power condition (i.e., the power off condition), enter step 714, an operational power source is provided through power detection module 220 (see FIG. 2) to controlled device 290, and then enter step 718, controlled device 290 is switched by infrared transmitter 260.

It is known from FIG. 7, the following corresponding steps (for example, the controlled device is reset, the power source to the controlled device is provided) after the power condition of controlled device 290 is determined in FIG. 2 are all for controlled device 290 to finally go back to the normal power condition. Controlled device 290 then can keep being operated and be continuously switched by infrared transmitter 260.

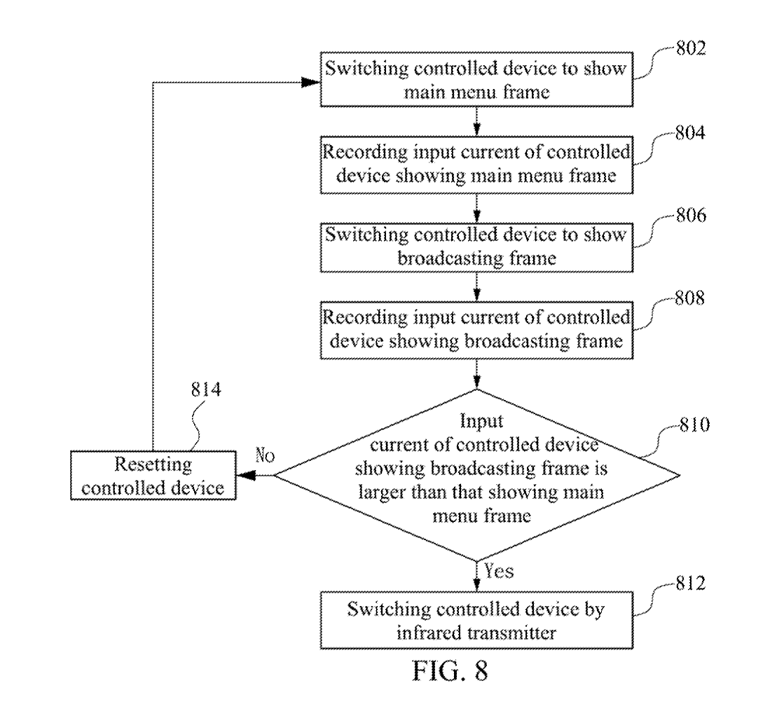

FIG. 8 illustrates a flowchart of a detecting method according to another embodiment of the invention. Similarly, please refer to FIG. 2 and FIG. 8 for better understanding. At first, controlled device 290 is switched to show a main menu frame (step 802), an input current of controlled device 290 showing the main menu frame is recorded (step 804), then controlled device 290 is switched to show a broadcasting frame (step 806), an input current of controlled device 290 showing the broadcasting frame is recorded (step 808), afterwards, the input current of controlled device 290 showing the main menu frame and that showing the broadcasting frame are compared with each other to determine whether the input current of controlled device 290 showing the broadcasting frame is larger than that showing the main menu frame (step 810). All the steps mentioned above can be realized by processing unit 240 in FIG. 2 or other processing units.

If the input current of controlled device 290 showing the broadcasting frame is larger than that showing the main menu frame, enter step 812, controlled device 290 is switched by infrared transmitter 260; if not, enter step 814, controlled device 290 is reset, then go back to step 802, a new detecting flow is started all over again.

The order of all the steps mentioned in the embodiments can be adjusted according to the actual situation except for those steps which are exclusively indicated. The flowcharts in FIG. 7 and FIG. 8 are merely two embodiments and are not limited to the invention.

From the embodiments of the invention, the insufficiency of the prior art can be improved by applying the detection device mentioned above to avoid the user incorrectly operate the controlled device without knowing the power condition of the controlled device. Furthermore, when the external power source device of the controlled device is damaged and the controlled device is in the power off condition, the spare external input power source can be converted to the operational power source to be reused by the controlled device.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A detection device electrically connected to a controlled device through a power line and configured for detecting a power condition of the controlled device, the detection device comprising:
a power detection module configured for detecting an input current transmitted through the power line from the controlled device and converting the input current to an output voltage signal;
a processing unit electrically connected to the power detection module, configured for receiving the output voltage signal and determining the power condition of the controlled device based on a voltage level of the output voltage signal; and
an infrared transmitter electrically connected to the processing unit, configured for transmitting an infrared signal based on a determined result of the processing unit to switch the controlled device such that the controlled device performs a corresponding operation.

2. The detection device of claim 1, wherein the power detection module further comprises:
a current sensor configured for sensing the input current and outputting a current signal corresponding to the input current;
a converter electrically connected to the current sensor, configured for converting the current signal to an internal voltage signal;
a voltage amplifier electrically connected to the converter, configured for amplifying the internal voltage signal to generate the output voltage signal; and
a power switch electrically connected to the current sensor and the processing unit and controlled by the processing unit to conduct or block the input current flowing to the current sensor.

3. The detection device of claim 1, wherein, when a value of the input current is in a first range, the processing unit determines that the controlled device is in a normal power condition; when the value of the input current is in a second range, the processing unit determines that the controlled device is in a fault power condition; when the value of the input current is in a third range, the processing unit determines that the controlled device is in a standby or a sleeping power condition; and when the value of the input current is in a fourth range, the processing unit determines that the controlled device is in a power off condition.

4. The detection device of claim 3, wherein when the processing unit determines that the controlled device is in the normal power condition, the standby power condition, or the sleeping power condition, the processing unit controls the infrared transmitter to switch the controlled device.

5. The detection device of claim 3, wherein when the processing unit determines that the controlled device is in the fault power condition, the processing unit resets the controlled device.

6. The detection device of claim 3, further comprising:
a power conversion module electrically connected to the processing unit and the power detection module and controlled by the processing unit, the power conversion module configured for converting an external power source to an operational power source for the power detection module.

7. The detection device of claim 6, wherein when the processing unit determines that the controlled device is in the power off condition, the power conversion module provides the operational power source for the controlled device through the power detection module.

8. A detecting method for detecting a controlled device, the detecting method comprising the steps of:
detecting an input current which is transmitted from the controlled device through a power line by a power detection module under different power conditions of the controlled device;
recording information corresponding to the input current; and
determining the power condition of the controlled device in accordance with the information corresponding to the input current.

9. The detecting method of claim 8, further comprising the steps of:
comparing the input current of the controlled device showing a main menu frame with the input current of the controlled device showing a broadcasting frame, and resetting the controlled device if the input current of the controlled device showing the broadcasting frame is smaller than the input current of the controlled device showing the main menu frame.

10. The detecting method of claim 8, further comprising the step of:
converting the input current to an output voltage signal;
wherein the step of determining the power condition of the controlled device further comprises the step of:
determining the power condition of the controlled device according to a voltage level of the output voltage signal.

11. The detecting method of claim 10, wherein the step of determining the power condition of the controlled device further comprises the steps of:
determining that the controlled device is in a normal power condition when the input current is in a first range;
determining that the controlled device is in a fault power condition when the input current is in a second range;
determining that the controlled device is in a standby or a sleeping power condition when the input current is in a third range; and
determining that the controlled device is in a power off condition when the input current is in a fourth range.

12. The detecting method of claim 11, further comprising the step of:
switching the controlled device by an infrared transmitter when the determined controlled device is in the normal power condition, the standby power condition, or the sleeping power condition.

13. The detecting method of claim 11, further comprising the step of:
resetting the controlled device when the determined controlled device is in the fault power condition.

14. The detecting method of claim 11, further comprising the step of:
providing an operational power source through the power detection module for the controlled device when the controlled device is in the power off condition.
